(19) United States
(12) Patent Application Publication
(10) Pub. No.: US 2014/0368089 A1
(43) Pub. Date: Dec. 18, 2014

(54) PIEZOELECTRIC VIBRATING PIECE, PIEZOELECTRIC DEVICE, AND METHOD FOR FABRICATING THE PIEZOELECTRIC DEVICE

(71) Applicant: NIHON DEMPA KOGYO CO., LTD., Tokyo (JP)

(72) Inventor: RYOTA OMOMO, SAITAMA (JP)

(73) Assignee: NIHON DEMPA KOGYO CO., LTD., Tokyo (JP)

(21) Appl. No.: 14/295,354

(22) Filed: Jun. 4, 2014

(30) Foreign Application Priority Data
Jun. 12, 2013 (JP) 2013-123740

(51) Int. Cl. H01L 41/053; H03H 9/17

(52) U.S. Cl. CPC H01L 41/053; H03H 9/17
USPC 310/348; 310/365

(57) ABSTRACT

A piezoelectric vibrating piece includes an excitation electrode and an extraction electrode. The excitation electrode is formed in a vibrating portion. The extraction electrode is extracted from the excitation electrode to one side portion. The piezoelectric vibrating piece includes a front surface and a back surface. At least one of the front surface and the back surface includes an index mark formed in a region. The region includes at least a part of a side portion on an opposite side of the one side portion. The region allows application of an adhesive.

### CROSS REFERENCE TO RELATED APPLICATIONS

This application claims the priority benefit of Japan application serial no. 2013-123740, filed on Jun. 12, 2013. The entirety of the above-mentioned patent application is hereby incorporated by reference herein and made a part of this specification.

### TECHNICAL FIELD

This disclosure relates to a piezoelectric vibrating piece, a piezoelectric device, and a method for fabricating the piezoelectric device.

### DESCRIPTION OF THE RELATED ART

Electronic equipment such as a mobile terminal and a mobile phone includes a piezoelectric device such as a piezoelectric resonator and an oscillator. The piezoelectric device includes a cavity and a piezoelectric vibrating piece such as a quartz crystal piece. The piezoelectric device is constituted by housing the piezoelectric vibrating piece in the cavity in a package constituted by a lid and a base. The piezoelectric vibrating piece of the piezoelectric device includes an excitation electrode and an extraction electrode. The excitation electrode is formed at the center. The extraction electrode is formed by being extracted from the excitation electrode to an end portion at one end side. It is known that the piezoelectric vibrating piece is bonded to the base at least at two points at the one end side or at the total of three points of the two points and one point at the other end side via an adhesive (see Japanese Unexamined Patent Application Publication No. 2008-206002, hereinafter referred to as Patent Literature 1).

When the piezoelectric vibrating piece is mounted to the base, for example, an adhesive is preliminary applied at a predetermined portion of the piezoelectric vibrating piece. Then, the piezoelectric vibrating piece and the base are aligned, and the piezoelectric vibrating piece is bonded to a position to be bonded on the base. However, if the piezoelectric vibrating piece is made of a transparent or translucent material such as a crystal, recognizing an outer edge of the piezoelectric vibrating piece is difficult. This makes it difficult to confirm the mounted position of the piezoelectric vibrating piece to the base. Furthermore, if the piezoelectric vibrating piece is transparent, when an adhesive is applied at the predetermined portion of the piezoelectric vibrating piece, it is difficult to confirm an amount of application of the adhesive and a position where the adhesive is applied. Consequently, this possibly causes a problem of insufficient bonding strength between the piezoelectric vibrating piece and the base.

Patent Literature 1 discloses the following. A dummy pattern for reflecting laser light is formed on a surface of a piezoelectric vibrating piece. Then, a mounting of the piezoelectric vibrating piece was inspected using a laser displacement sensor. However, the dummy pattern disclosed in Patent Literature 1 does not allow recognizing a side portion of the piezoelectric vibrating piece. This arises a problem that confirming a mounted position relative to a base in a surface direction is difficult. Furthermore, if an adhesive is applied to this dummy pattern, since the dummy pattern does not have a relative region to the adhesive, this causes a problem that an amount of application of the applied adhesive and a position where the adhesive is applied are difficult to check.

A need thus exists for a piezoelectric vibrating piece, a piezoelectric device, and a method for fabricating the piezoelectric device which are not susceptible to the drawback mentioned above.

### SUMMARY

A piezoelectric vibrating piece according to the disclosure includes an excitation electrode and an extraction electrode. The excitation electrode is formed in a vibrating portion. The extraction electrode is extracted from the excitation electrode to one side portion. The piezoelectric vibrating piece includes a front surface and a back surface. At least one of the front surface and the back surface includes an index mark formed in a region. The region includes at least a part of a side portion on an opposite side of the one side portion. The region allows application of an adhesive.

### BRIEF DESCRIPTION OF THE DRAWINGS

The foregoing and additional features and characteristics of this disclosure will become more apparent from the following detailed description considered with reference to the accompanying drawings.

FIG. 1A is a plan view illustrating a piezoelectric vibrating piece according to a first embodiment.

FIG. 1B is a cross-sectional view taken along the line IB-IB of FIG. 1A.

FIG. 2 is a plan view illustrating a piezoelectric vibrating piece according to a second embodiment.

FIG. 3 is a plan view illustrating a piezoelectric vibrating piece according to a third embodiment.

FIG. 4 is a plan view illustrating a piezoelectric vibrating piece according to a fourth embodiment.

FIG. 5A is a plan view illustrating a piezoelectric vibrating piece according to a fifth embodiment.

FIG. 5B is a cross-sectional view taken along the line VB-VB of FIG. 5A.

FIG. 6A is a plan view illustrating an embodiment of a piezoelectric device.

FIG. 6B is a cross-sectional view taken along the line VIB-VIB of FIG. 6A.

FIG. 7 is a plan view illustrating a base of the piezoelectric device illustrated in FIGS. 6A and 6B.

FIGS. 8A and 8B are cross-sectional views illustrating a modification of the embodiment of the piezoelectric device.

FIG. 9 is a flowchart illustrating a fabrication process of the piezoelectric device illustrated in FIGS. 6A and 6B.

FIGS. 10A and 10B illustrate a fabrication process of the piezoelectric device illustrated in FIGS. 6A and 6B.

FIGS. 11A and 11B illustrate a fabrication process of the piezoelectric device illustrated in FIGS. 6A and 6B.

### DETAILED DESCRIPTION

Hereinafter, a description will be given of embodiments disclosed here with the reference to the accompanying drawings. However, this disclosure is not limited to this. In order to describe the embodiments, the drawings are expressed by changing the scale as necessary. For example, the illustration is partially enlarged or emphasized. In the drawings, a hatched portion represents a metal film, an adhesive, and a bonding material. In each drawing below, an XYZ coordinate system is used to describe directions in the drawings. In this XYZ coordinate system, a plane parallel to the front surface of a piezoelectric vibrating piece is assumed to be an XZ plane. On this XZ plane, a longitudinal direction of the piezoelectric vibrating piece is indicated as X direction, and a direction orthogonal to the X direction is indicated as Z direction. A direction perpendicular to the XZ plane (thickness direction of the piezoelectric vibrating piece) is indicated as Y direction. In the description, a direction pointed by an arrow is assumed to be a + direction in each of X, Y, and Z directions. The direction opposite of that is assumed to be a − direction.

### Constitution of Piezoelectric Vibrating Piece 10 of First Embodiment

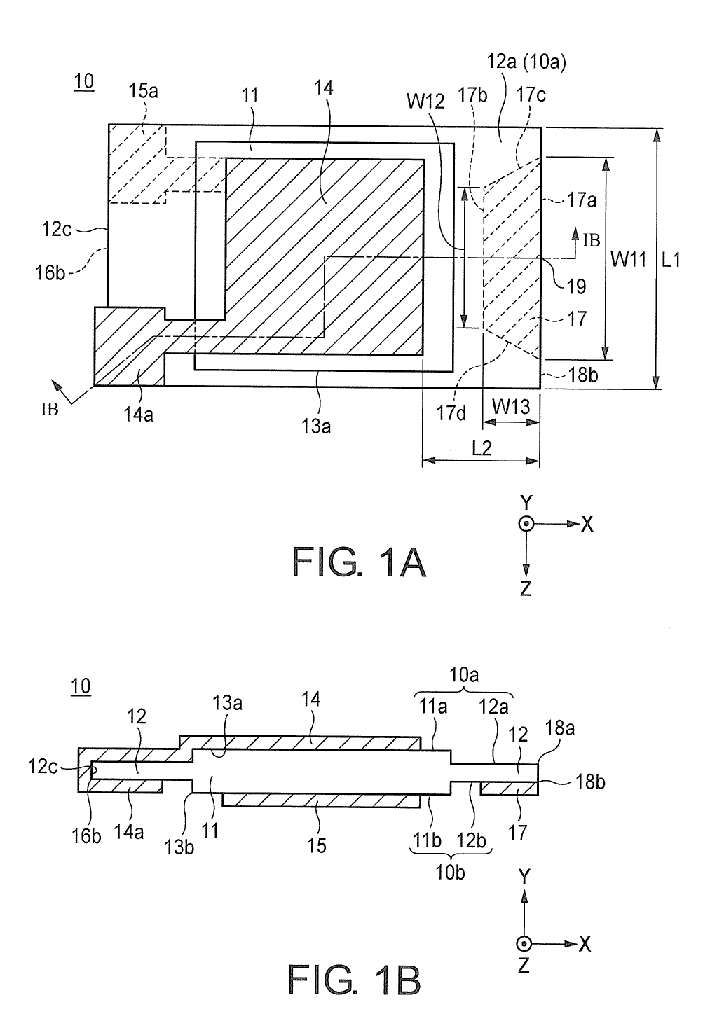

A description will be given of a piezoelectric vibrating piece 10 according to the first embodiment with reference to FIGS. 1A and 1B. For example, an AT-cut quartz-crystal material is used as the piezoelectric vibrating piece 10. AT-cut has advantages that satisfactory frequency characteristics are obtained when a crystal unit is used at around ordinary temperature, for example, and is a processing method for cutting out the crystal unit at an angle inclined at 35°15′ around the crystallographic axis with respect to the optical axis among the electric axis, the mechanical axis, and the optical axis, which are three crystallographic axes of the synthetic quartz crystal. This method is also similar to a second to a fifth embodiments described later.

As illustrated in FIGS. 1A and 1B, the piezoelectric vibrating piece 10 is formed of a rectangular plate-shaped member having a long side in the X direction and a short side in the Z direction. The piezoelectric vibrating piece 10 includes a vibrating portion 11 and a peripheral portion 12. As illustrated in FIG. 1A, the vibrating portion 11 is formed at the central portion of the piezoelectric vibrating piece 10 viewed from the Y-axis direction. As illustrated in FIGS. 1A and 1B, the peripheral portion 12 is formed at the region surrounding the vibrating portion 11 viewed from the Y direction.

As illustrated in FIGS. 1A and 1B, the vibrating portion 11 forms a mesa portion 13a on the front surface (+Y-side surface). The mesa portion 13a is formed to be higher in the +Y direction than the peripheral portion 12. Meanwhile, the vibrating portion 11 forms a mesa portion 13b on the back surface (−Y-side surface). The mesa portion 13b is formed to be higher in the −Y direction than the peripheral portion 12. Disposing the mesa portions 13a and 13b efficiently confines the vibration energy of the piezoelectric vibrating piece 10, so as to reduce a CI value (a crystal impedance value). There is no need to include one or both of the mesa portions 13a and 13b. When the mesa portion 13a is not disposed, the vibrating portion 11 has a front surface in the same plane as a front surface (+Y-side surface) 12a of the peripheral portion 12. When the mesa portion 13b is not disposed, the vibrating portion 11 has a back surface in the same plane as a back surface (−Y-side surface) 12b of the peripheral portion 12.

The vibrating portion 11 includes an excitation electrode 14 on the front surface. The vibrating portion 11 includes an excitation electrode 15 on the back surface. As illustrated in FIG. 1A, the excitation electrodes 14 and 15 are formed into a rectangular shape within the mesa portions 13a and 13b regions viewed from the Y direction. Applying a predetermined voltage to the excitation electrodes 14 and 15 vibrates the vibrating portion 11 at a predetermined vibration frequency.

An extraction electrode 14a is formed on the front surface 12a of the peripheral portion 12. The extraction electrode 14a is extracted from the excitation electrode 14 in the −X direction and is extracted to a side portion 16b at the −X-side of the piezoelectric vibrating piece 10. The extraction electrode 14a is extracted to the region at the −X-side and the +Z-side on the back surface 12b of the peripheral portion 12 via a side surface 12c at the −X-side of the peripheral portion 12. The extraction electrode 14a is electrically connected to the excitation electrode 14. The extraction electrode 14a is formed on the side surface 12c at the −X-side in FIG. 1A. Meanwhile, the extraction electrode 14a may be formed on the side surface 12c at the +Z-side.

An extraction electrode 15a is disposed on the back surface 12b of the peripheral portion 12. The extraction electrode 15a is extracted from the excitation electrode 15 in the −X direction. The extraction electrode 15a is formed to the side portion 16b at the −X-side of the piezoelectric vibrating piece 10. The extraction electrode 15a is electrically connected to the excitation electrode 15.

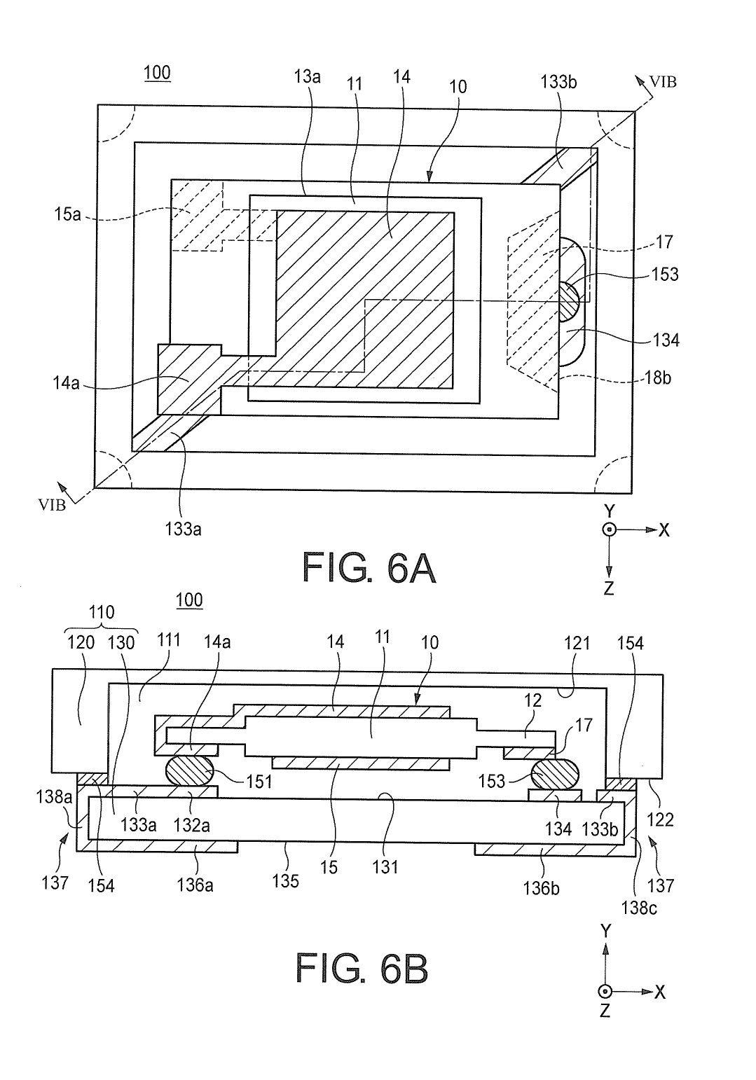

An index mark 17 is disposed on the back surface 12b (a back surface 10b of the piezoelectric vibrating piece 10) of the peripheral portion 12. The index mark 17 includes an end portion 17a at the +X-side. The end portion 17a includes a part of a side portion 18b. The side portion 18b is a short side at the +X-side on the back surface 10b of the piezoelectric vibrating piece 10 and is also a side portion of the opposite side (the +X-side of the piezoelectric vibrating piece 10) of the side portion 16b with the extraction electrode 15a. The index mark 17 is not formed at the −Z- and +Z-sides of the side portion 18b. The index mark 17 is disposed in the region inner side with respect to the −X-side of the side portion 18b so as to include the position where an adhesive 153 is to be applied (See FIGS. 6A and 6B and other drawings). In this embodiment, an exemplary position where the adhesive 153 is to be applied is set to a region including a middle point 19 of the side portion 18b (See FIG. 6A). The index mark 17 is disposed at the region that includes the middle point 19 of the side portion 18b.

As illustrated in FIG. 1A, the index mark 17 is formed on the region surrounded by the end portion 17a at the +X-side, an end portion 17b at the −X-side, and outer edge portions 17c and 17d. The outer edge portion 17c connects the end point at the −Z-side of the end portion 17a and the end point at the −Z-side of the end portion 17b and is formed into a linear line. The outer edge portion 17d connects the end point at the +Z-side of the end portion 17a and the end point at the +Z-side of the end portion 17b and is formed into a linear line.

The index mark 17 is set so that a width (a width of the end portion 17a in the Z-axis direction) W11 of the side portion 18b is larger than a width (a width of the end portion 17b in the Z-axis direction) W12 of the central side. The width W11 is set so as to have the length between the one-half and the four-fifths of a width L1 of the side portion 18b, for example. A width (a distance of the end portion 17b to the end portion 17a in the X-axis direction) W13 in the X-axis direction is set so as to be smaller than a distance L2 of the excitation electrodes 14 and 15 to the side portion 18b in the X-axis direction. The width W13 is set so as to have the one-half or less of the distance L2, for example.

The index mark 17 is formed into a trapezoidal shape where the end portion 17b, the end portion 17a, the outer edge portions 17c and 17d, and the width W13 are an upper bottom, a lower bottom, legs, and a height, respectively, viewed from the Y-axis direction. The index mark 17 is formed symmetrically with respect to a straight line passing through the middle point 19 of the side portion 18b in the X-axis direction. The adhesive 153 can be applied to the region of the index mark 17.

The index mark 17 is not limited to the trapezoidal shape described above. For example, the index mark 17 may be formed into a curved line shape in place of forming one or both of the outer edge portions 17c and 17d into a linear line. The index mark 17 may be formed asymmetrically with respect to a straight line passing through the middle point 19 in the X-axis direction. The index mark 17 may be formed on a front surface 10a in place of being formed on the back surface 10b of the piezoelectric vibrating piece 10. This is also similar to a second to a fourth embodiments described below. In this case, the index mark 17 is formed so as to include at least a part of a side portion 18a on the front surface (+Y-side surface) of the piezoelectric vibrating piece 10.

The index mark 17 is a conductive metal film similar to the excitation electrodes 14 and 15 and the extraction electrodes 14a and 15a. The index mark 17 is formed of the same film structure as an integrated metal film. The conductive metal films have a layered structure where, for example, a nickel tungsten (NiW), a nickel (Ni), a chrome (Cr), a titanium (Ti), a nickel chrome (NiCr), or a nickel titanium (NiTi) is formed as a foundation film used for ensuring adhesion with a quartz-crystal material, which is the piezoelectric vibrating piece 10, on which a gold (Au) or a silver (Ag) is formed as a conductive film.

A part or all of the excitation electrodes 14 and 15, the extraction electrodes 14a and 15a, and the index mark 17 may be formed of different film structures or different materials. For example, the index mark 17 may be formed of a metal film of one of the foundation film or the conductive film. The index mark 17 may be formed of a non-conductive metal film. The index mark 17 is not be limited to be the metal film. The index mark 17, for example, may be a material using resin or ceramics, a material obtained by varying a reflectivity while varying a surface property of the piezoelectric vibrating piece 10, a colored material obtained by applying an ink, or a similar color material. The material of the index mark 17 described above is also similar to the second to the fourth embodiments described later.

For example, in the piezoelectric vibrating piece 10, conductive adhesives 151 and 152, which will be described later, and the adhesive 153 are applied on the extraction electrodes 14a and 15a and the index mark 17 on the back surface 10b. The extraction electrodes 14a and 15a and the index mark 17 are bonded to a front surface (+Y-side surface) 131 of a base 130 of a package 110, which will be described later, via the adhesives 151, 152, and 153. Thus, the piezoelectric vibrating piece 10 is supported at three points of the base 130: a part at the −X-side and the −Z-side, a part at the −X-side and the +Z-side, and the middle point 19 of the side portion 18b at the +X-side (hereinafter referred to as the three-point support). The piezoelectric vibrating piece 10 may be held on the base 130 by the two-point support in place of being held by the three-point support. In the two-point support, the conductive adhesives 151 and 152 are applied to the extraction electrodes 14a and 15a, and the adhesive 153 is not applied on the index mark 17 for bonding to the base 130. The piezoelectric vibrating piece 10 is supported on the base 130 in a cantilevered condition by the two-point support.

Thus, according to the first embodiment, since the index mark 17 is formed in the side portion 18b, this can identify the outer edge of the piezoelectric vibrating piece 10 easily and, for example, facilitates to know the positional relationship with the base 130 or a similar member easily. For example, when the image of the piezoelectric vibrating piece 10 is obtained by an imaging apparatus equipped with an image sensor such as a CCD and a CMOS, the outer edge of the piezoelectric vibrating piece 10 can be identified in the image by the index mark 17. Thus, the mounting position can be determined exactly by the image or a similar method when the piezoelectric vibrating piece 10 is mounted on the base 130 described later.

Since the index mark 17 includes the widths W11, W12, and W13, the region on which the adhesive is applicable can be reliably ensured on the index mark 17. Since the index mark 17 includes the width W11 and a similar width, the index mark 17 does not hide even if the adhesive is applied. Comparing the index mark 17 with the adhesive allows easily determining whether or not a position where the adhesive is to be applied and an amount of application are appropriate.

Since the index mark 17 is established so that the width W12 of the end portion 17b close to the excitation electrodes 14 and 15 is smaller than the width W11 of the end portion 17a, an effect on a vibration characteristic of the vibrating portion 11 can be reduced. Expanding the width W11 of the end portion 17a allows recognizing the side portion 18b in a wide range.

Even if the index mark 17 is formed on the front surface 10a in place of forming the index mark 17 on the back surface 10b of the piezoelectric vibrating piece 10, the index mark 17 has the similar effect as when the index mark 17 is formed on the back surface 10b. When the index mark 17 is formed on the back surface 10b, the extraction electrodes 14a and 15a disposed on the back surface side and the index mark 17 are arranged on substantially the same plane. Thus, a distance of the index mark 17 to the imaging apparatus and a distance of the extraction electrodes 14a and 15a to the imaging apparatus are the same. Thus, the index mark 17 or a similar member can be set to be within the range of the depth of focus in the imaging apparatus easily.

### Method for Fabricating Piezoelectric Vibrating Piece 10

Next, a description will be given of a method for fabricating the piezoelectric vibrating piece 10. First, a piezoelectric wafer is prepared. For the piezoelectric vibrating pieces 10, a multiple patterning is performed on a piezoelectric wafer from which individual piezoelectric vibrating pieces 10 are cut out. The piezoelectric wafer is cut out from a quartz crystal in a predetermined thickness by the AT-cut. Then, the piezoelectric wafer is formed by, for example, etching or cutting such that the thickness (width in the Y-axis direction) of a part where the vibrating portion is to be formed is thinned, and is adjusted such that the vibrating portion has the desired frequency characteristic. The mesa portions 13a and 13b are formed on the front surface 10a and the back surface 10b of the piezoelectric vibrating piece 10 by the photolithography and etching. Next, the excitation electrodes 14 and 15, the extraction electrodes 14a and 15a, and the index mark 17 are formed on portions that will be the front surface 10a, the back surface 10b, and a side surface 10c of the piezoelectric wafer.

The excitation electrodes 14 and 15, the extraction electrodes 14a and 15a, and the index mark 17 are formed by forming and patterning the conductive metal film with the photolithography and etching. The conductive metal films such as a nickel tungsten (NiW) are first formed as a foundation film, used for ensuring adhesion with a quartz-crystal material, which is the piezoelectric vibrating piece 10, on which, for example, a silver (Ag) is next formed as a conductive film. Next, the respective electrode 14 and a similar electrode and the index mark 17 are formed by patterning the conductive metal film by the etching.

The excitation electrodes 14 and 15, the extraction electrodes 14a and 15a, and the index mark 17 are formed approximately at the same time by forming and patterning the conductive metal film described above. However, the excitation electrodes 14 and 15, the extraction electrodes 14a and 15a, and the index mark 17 may be formed separately. The patterned conductive metal film may be formed by, for example, sputtering or vacuum evaporation using a metal mask stencil in place of the photolithography and etching. After the respective electrodes 14 and similar electrodes and the index mark 17 are formed, the piezoelectric wafer is diced along the scribe line. Accordingly, the individual piezoelectric vibrating pieces 10 are completed.

Therefore, the index mark 17 can be made of the same material and can have the same process as the excitation electrodes 14 and 15, and the extraction electrodes 14a and 15a. Thus, the increase in the fabrication cost caused by forming the index mark 17 on the piezoelectric vibrating piece 10 can be reduced.

### Second Embodiment

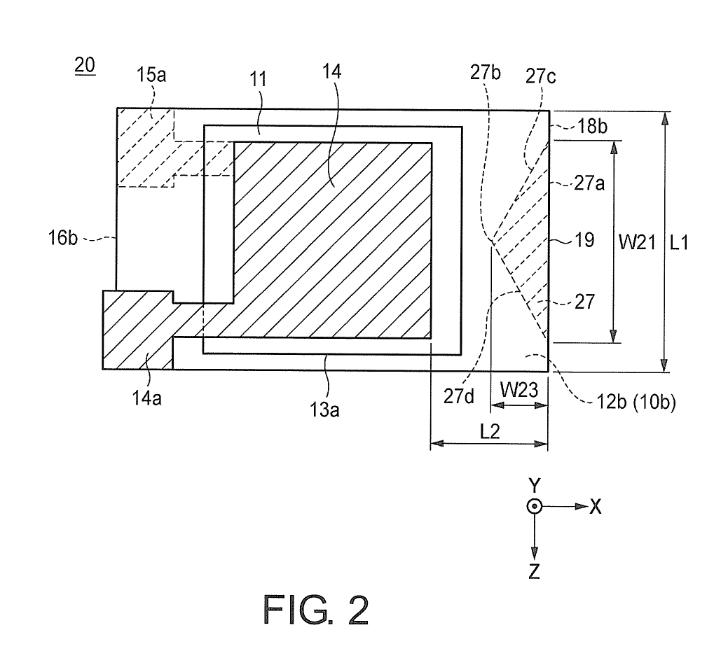

Next, a description will be given of a piezoelectric vibrating piece 20 according to the second embodiment with reference to FIG. 2. In the following description, like reference numerals designate identical or corresponding parts of the first embodiment, and therefore such elements will not be further elaborated here. Since the piezoelectric vibrating piece 20 according to this embodiment includes an index mark 27 in place of the index mark 17 of the first embodiment, the piezoelectric vibrating piece 20 differs from the piezoelectric vibrating piece 10 illustrated in FIGS. 1A and 1B.

As illustrated in FIG. 2, the piezoelectric vibrating piece 20 includes the index mark 27 on the back surface 12b of the peripheral portion 12. The index mark 27 includes an end portion 27a at the +X-side. The end portion 27a includes a part of the side portion 18b. The index mark 27 is not disposed at the −Z- and +Z-sides of the side portion 18b. Similarly to the index mark 17 illustrated in FIGS. 1A and 1B, the index mark 27 is disposed in the region inner side with respect to the −X-side of the side portion 18b so as to include the position where the adhesive 153 is to be applied. In this embodiment, the position where the adhesive 153 is to be applied is set to a region including the middle point 19 of the side portion 18b. The index mark 27 is disposed at the region that includes the middle point 19 of the side portion 18b.

As illustrated in FIG. 2, the index mark 27 is formed on the region surrounded by the end portion 27a at the +X-side, an end portion 27b at the −X-side, and outer edge portions 27c and 27d. The outer edge portion 27c connects the end point at the −Z-side of the end portion 27a and the end portion 27b and is formed into a linear line. The outer edge portion 27d connects the end point at the +Z-side of the end portion 27a and the end portion 27b and is formed into a linear line. The index mark 27 includes a width (a width of the end portion 27a in the Z-axis direction) W21 of the side portion 18b and a width (a distance from the end portion 27b to the end portion 27a in the X-axis direction) W23 in the X-axis direction. The width W21 is set so as to have the length, for example, between the one-half and the four-fifths of the width L1 of the side portion 18b. The width W23 is set so as to be smaller than the distance L2. The width W23 is set so as to have the one-half or less of the distance L2, for example.

The index mark 27 is formed into a triangular shape where the end portion 27b at the −X-side, the end portion 27a at the +X-side, and a width W23 are respectively an end point, a bottom side, and a height, viewed from the Y-axis direction. The index mark 27 is formed symmetrically with respect to a straight line passing through the middle point 19 of the side portion 18b in the X-axis direction. The adhesive 153 can be applied to the region of the index mark 27. The index mark 27 is not limited to the shape described above. For example, the index mark 27 may be formed into a curved line shape in place of forming one or both of the outer edge portions 27c and 27d into a linear line. The index mark 27 may be formed asymmetrically with respect to a straight line passing through the middle point 19 in the X-axis direction. The index mark 27 is similar to the index mark 17 illustrated in FIGS. 1A and 1B in that the conductive metal film similar to the excitation electrode 14 or a similar electrode is used.

Thus, according to the second embodiment, this has the similar effect to the effect described in the first embodiment. Since the index mark 27 does not have a width (a length in the Z-axis direction) at the central side, an effect on a vibration characteristic of the vibrating portion 11 can be more reliably reduced. The fabrication method of the piezoelectric vibrating piece 20 is substantially similar to the fabrication method of the piezoelectric vibrating piece 10 described above.

### Third Embodiment

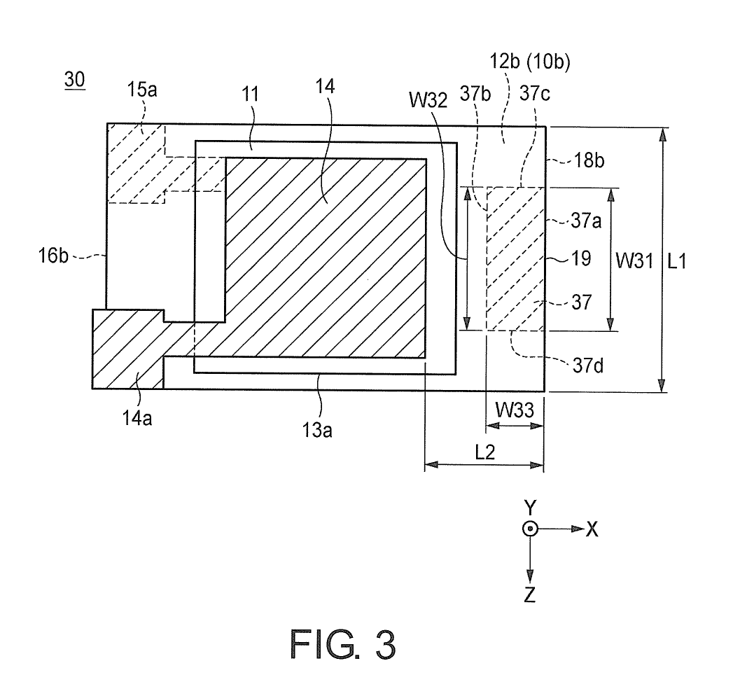

Next, a description will be given of a piezoelectric vibrating piece 30 according to the third embodiment with reference to FIG. 3. In the following description, like reference numerals designate identical or corresponding parts of the first embodiment, and therefore such elements will not be further elaborated here. Since the piezoelectric vibrating piece 30 according to this embodiment includes an index mark 37 in place of the index mark 17 of the first embodiment, the piezoelectric vibrating piece 30 differs from the piezoelectric vibrating piece 10 illustrated in FIGS. 1A and 1B.

As illustrated in FIG. 3, the piezoelectric vibrating piece 30 includes the index mark 37 on the back surface 12b of the peripheral portion 12. The index mark 37 includes an end portion 37a at the +X-side. The end portion 37a includes a part of the side portion 18b. The index mark 37 is not disposed at the −Z- and +Z-sides of the side portion 18b. Similarly to the index mark 17 illustrated in FIGS. 1A and 1B, the index mark 37 is disposed in the region that includes the position where the adhesive 153 is to be applied. In this embodiment, the position where the adhesive 153 is to be applied is set to a region including the middle point 19 of the side portion 18b. The index mark 37 is disposed in the region that includes the middle point 19 of the side portion 18b.

As illustrated in FIG. 3, the index mark 37 is formed on the region surrounded by the end portion 37a at the +X-side, an end portion 37b at the −X-side, and outer edge portions 37c and 37d. The outer edge portion 37c connects the end point at the −Z-side of the end portion 37a and the end point at the −Z-side of the end portion 37b and is formed into a linear line. The outer edge portion 37d connects the end point at the +Z-side of the end portion 37a and the end point at the +Z-side of the end portion 37b and is formed into a linear line.

The index mark 37 is set so that a width (a width of the end portion 37a in the Z-axis direction) W31 of the side portion 18b has a length substantially the same as a width (a width of the end portion 37b in the Z-axis direction) W32 of the central side. The width W31 is set so as to have the length, for example, between the one-half and the four-fifths of the width L1 of the side portion 18b. A width (a distance from the end portion 37b to the end portion 37a in the X-axis direction) W33 in the X-axis direction is set so as to be smaller than the distance L2. The width W33 is set so as to have the one-half or less of the distance L2, for example.

The index mark 37 is formed into a rectangular shape where the end portion 37b at the −X-side and the end portion 37a at the +X-side are the long sides, and the outer edge portion 37c at the −Z-side and outer edge portion 37d at the +Z-side are the short sides viewed from the Y-axis direction. The index mark 37 is formed symmetrically with respect to a straight line passing through the middle point 19 of the side portion 18b in the X-axis direction. The adhesive 153 can be applied to the region of the index mark 37. The index mark 37 is not limited to the shape described above. For example, the index mark 37 may be formed into a curved line shape in place of forming a part or all of the end portion 37b and the outer edge portions 37c and 37d into a linear line. The index mark 37 may be formed asymmetrically with respect to a straight line passing through the middle point 19 in the X-axis direction. The index mark 37 is similar to the index mark 17 illustrated in FIGS. 1A and 1B in that the conductive metal film similar to the excitation electrode 14 or a similar electrode is used.

Thus, according to the third embodiment, this has the similar effect to the effect described in the first embodiment. In addition, since the index mark 37 is set so that the width W32 is substantially the same as the width W31, the region where the adhesive is to be applied can be widened. The fabrication method of the piezoelectric vibrating piece 30 is substantially similar to the fabrication method of the piezoelectric vibrating piece 10 described above.

### Fourth Embodiment

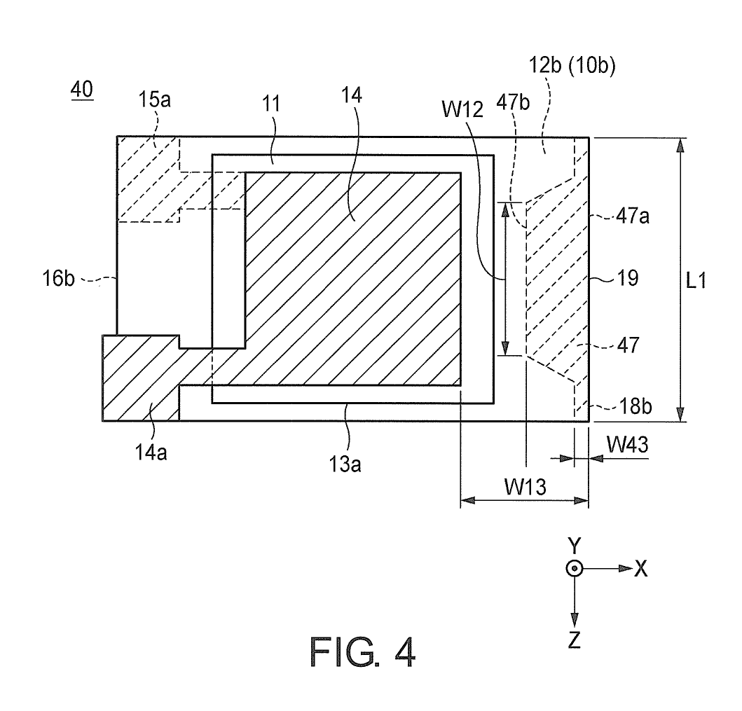

Next, a description will be given of a piezoelectric vibrating piece 40 according to the fourth embodiment with reference to FIG. 4. In the following description, like reference numerals designate identical or corresponding parts of the first embodiment, and therefore such elements will not be further elaborated here. Since the piezoelectric vibrating piece 40 according to this embodiment includes an index mark 47 in place of the index mark 17 of the first embodiment, the piezoelectric vibrating piece 40 differs from the piezoelectric vibrating piece 10 illustrated in FIGS. 1A and 1B.

As illustrated in FIG. 4, the piezoelectric vibrating piece 40 includes the index mark 47 on the back surface 12b of the peripheral portion 12. The index mark 47 includes an end portion 47a at the +X-side. The end portion 47a includes all of the side portion 18b. Similarly to the index mark 17 illustrated in FIGS. 1A and 1B, the index mark 47 is disposed in the region that includes the position where the adhesive 153 is to be applied. In this embodiment, the position where the adhesive 153 is to be applied is set to a region including the middle point 19 of the side portion 18b. The index mark 47 is disposed in the region that includes the middle point 19 of the side portion 18b.

As illustrated in FIG. 4, the index mark 47 is formed in the region combining the same trapezoidal shape as the index mark 17 illustrated in FIGS. 1A and 1B with a belt shape having a width (a length in the X-axis direction) W43 along the side portion 18b, viewed from the Y direction. The index mark 47 is formed so that the width W12 of an end portion 47b is similar to the width W12 of the index mark 17 illustrated in FIGS. 1A and 1B. The width W13 is also similar to the width W13 of the index mark 17 illustrated in FIGS. 1A and 1B. Any value can be set as the length of the width W43. The adhesive 153 can be applied to the region at the index mark 47.

The index mark 47 is not limited to the shape described above. For example, the index mark 47 may be formed by replacing the same trapezoidal shape part as the index mark 17 with the respective shapes having the index marks 27 and 37 according to the second and the third embodiments. The width W43 part formed into the belt shape does not have to be constant in the Z-axis direction. For example, the width W43 may be narrow at the end portion at the ±Z-sides (or set to zero) and gradually become wide toward the middle point 19. The index mark 47 may be formed asymmetrically with respect to a straight line passing through the middle point 19 in the X-axis direction. The index mark 37 is formed similarly to the index mark 17 illustrated in FIGS. 1A and 1B in that the conductive metal film similar to the excitation electrode 14 or a similar electrode is used.

Thus, according to the fourth embodiment, this has the similar effect to the effect described in the first embodiment. In addition, since the index mark 47 is formed in the region that includes all of the side portion 18b, the whole side portion 18b of the piezoelectric vibrating piece 40 can be identified exactly. On the other hand, since the width W12 of the end portion 47b is set to be small, an effect on a vibration characteristic of the vibrating portion 11 can be reduced. The fabrication method of the piezoelectric vibrating piece 40 is substantially similar to the fabrication method of the piezoelectric vibrating piece 10 described above.

### Fifth Embodiment

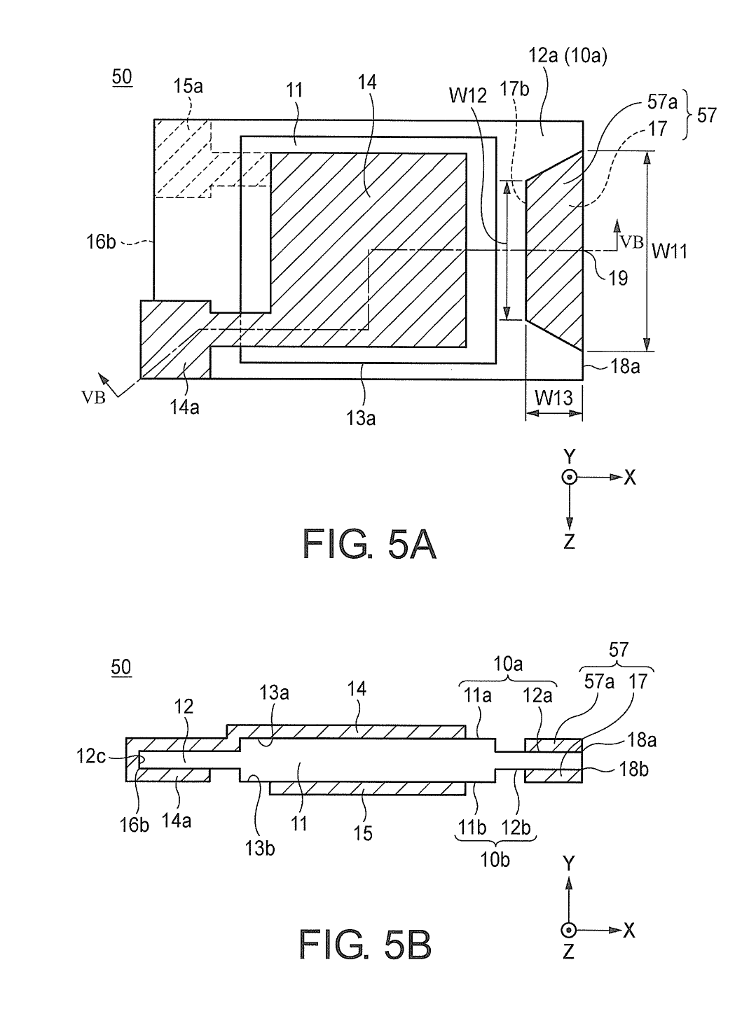

Next, a description will be given of a piezoelectric vibrating piece 50 according to the fifth embodiment with reference to FIGS. 5A and 5B. In the following description, like reference numerals designate identical or corresponding parts of the first embodiment, and therefore such elements will not be further elaborated here. Since the piezoelectric vibrating piece 50 according to this embodiment includes an index mark 57 in place of the index mark 17 of the first embodiment, the piezoelectric vibrating piece 50 differs from the piezoelectric vibrating piece 10 illustrated in FIGS. 1A and 1B.

As illustrated in FIGS. 5A and 5B, the piezoelectric vibrating piece 50 includes the index mark 57. The index mark 57 is constituted of the index mark 17 illustrated in FIGS. 1A and 1B and an index mark 57a. The index mark 57a is formed on the front surface 12a of the peripheral portion 12. The index mark 17 and the index mark 57a are formed into substantially the same trapezoidal shape viewed from the Y-axis direction. The index mark 17 and the index mark 57a are formed symmetrically with respect to the XZ plane that includes the center of thickness (a length in the Y-axis direction) of the piezoelectric vibrating piece 50. Therefore, the index mark 57a has the same portions as the end portions 17a and 17b, and the outer edge portions 17c and 17d of the index mark 17 described above, respectively.

The index mark 57 is not limited to the shape described above. For example, the similar portion to the forms of the index marks 27 to 47 according to the second to the fourth embodiments described above may be used on the front surface 12a and the back surface 12b of the peripheral portion 12. The index mark 17 and the index mark 57a are not limited to be formed into the same shape and symmetrically to each other. For example, the index mark 17 and the index mark 57a may have the mutually different shapes. The index mark 17 and the index mark 57a may shift in position from each other viewed from the Y-axis direction. The index mark 57a is similar to the index mark 17 illustrated in FIGS. 1A and 1B in that the conductive metal film similar to the excitation electrode 14 or a similar electrode is used. However, the index mark 17 and the index mark 57a may be made of different materials.

Thus, according to the fifth embodiment, this has the similar effect to the effect described in the first embodiment. In addition, the index mark is formed on both surfaces of the front surface 10a and the back surface 10b of the piezoelectric vibrating piece 50, when the piezoelectric vibrating piece 50 is formed of a non-permeable material, even if the index mark 17 on the back surface cannot be seen from the front surface of the piezoelectric vibrating piece 50, the edge portion can be identified by the index mark 57a. The fabrication method of the piezoelectric vibrating piece 50 is substantially similar to the fabrication method of the piezoelectric vibrating piece 10 described above. In addition to the fabrication method of the piezoelectric vibrating piece 10, the fabrication method of the piezoelectric vibrating piece 50 forms the index mark 17 and the index mark 57a at the same time.

### Piezoelectric Device

Next, a description will be given of an embodiment of a piezoelectric device 100. In the following description, like reference numerals designate identical or corresponding parts of the above-described embodiments, and therefore such elements will not be further elaborated here. A part of a lid 120 is transparently illustrated in FIG. 6A. As illustrated in FIGS. 6A and 6B, the piezoelectric device 100 includes the piezoelectric vibrating piece 10 and a package 110. The package 110 houses the piezoelectric vibrating piece 10. The package 110 includes the lid 120 and the base 130. While the lid 120 and the base 130 are made of a glass, the lid 120 and the base 130 may be made of a silicon, a ceramics, a resin, a metal, or a similar material in place of the glass.

As illustrated in FIG. 6B, the lid 120 includes a depressed portion 121 and a bonding surface 122. The depressed portion 121 is formed at the central portion of the back surface (−Y-side surface) of the lid 120. The bonding surface 122 surrounds the depressed portion 121. The depressed portion 121 is used as a space that houses the piezoelectric vibrating piece 10.

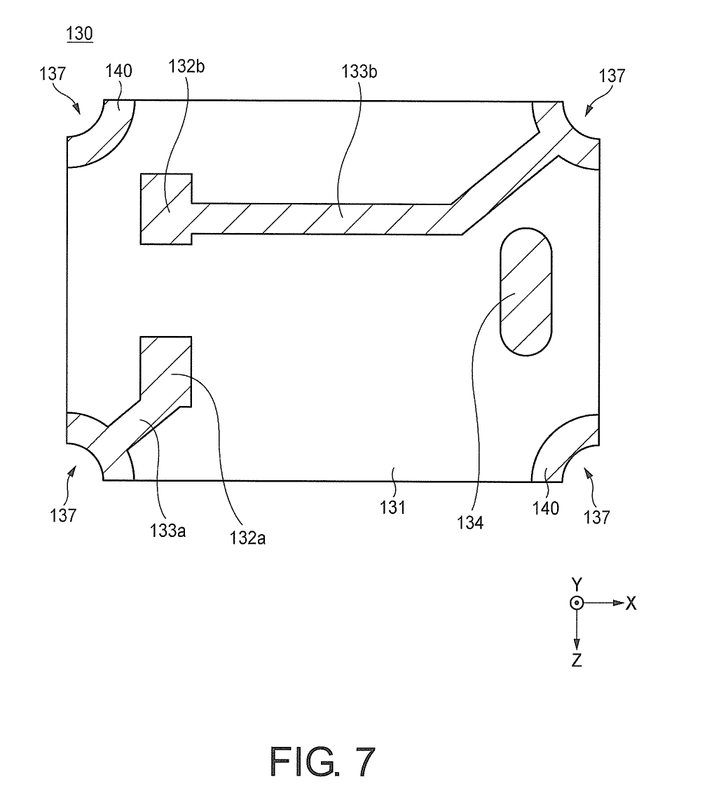

As illustrated in FIGS. 6A and 6B and FIG. 7, the base 130 has a plate shaped member. The base 130 forms connecting electrodes 132a and 132b, routing electrodes 133a and 133b, and a corresponding mark 134 on the front surface (+Y-side surface) 131. The routing electrodes 133a and 133b are electrically connected to the connecting electrodes 132a and 132b, respectively. The corresponding mark 134 is disposed corresponding to the index mark 17 of the piezoelectric vibrating piece 10. When the piezoelectric vibrating piece 10 is adhered and mounted on the package 110, a position where the piezoelectric vibrating piece 10 is held can be confirmed by observing the index mark 17 and the corresponding mark 134.

Forming the conductive metal film by, for example, sputtering or vacuum evaporation using, for example, a metal mask stencil allows forming the connecting electrodes 132a and 132b, the routing electrodes 133a and 133b, and the corresponding mark 134. The connecting electrodes 132a and 132b, the routing electrodes 133a and 133b, and the corresponding mark 134 may be formed by the photolithography and etching. The metal films have a layered structure where, for example, a nickel tungsten (NiW) is formed as a foundation film on which a silver (Ag) is formed as a conductive film, similarly to the excitation electrode 14 or a similar electrode of the piezoelectric vibrating piece 10. A chrome (Cr), a titanium (Ti), a nickel (Ni), a nickel chrome (NiCr), a nickel titanium (NiTi), or a similar material may be used as the foundation film. A gold (Au) or a similar material may be used for the conductive film.

The corresponding mark 134 is not limited to be formed of the same material as those of the connecting electrodes 132a and 132b and the routing electrodes 133a and 133b. For example, the corresponding mark 134 may be formed of a metal film of one of the foundation film or the conductive film. The corresponding mark 134 may be formed of a non-conductive metal film. The corresponding mark 134 may not be limited to be the metal film. The corresponding mark 134, for example, may be a material using resin or ceramics, a material obtained by varying a reflectivity while varying a surface property of the base 130, a colored material obtained by applying an ink, or a similar color material.

The base 130 includes external electrodes 136a and 136b on a back surface (−Y-side surface) 135. The external electrodes 136a and 136b are used as a pair of mounting terminals when the piezoelectric device 100 is mounted on a substrate or a similar member. Castellations 137 are disposed at the four corner portions of the base 130 on the ZX plane. The castellations 137 cuts off the corner portions in a curved surface shape toward the inside.

The castellation electrode 138a is formed at the corner portion at the −X- and the +Z-sides of the front surface of the castellation 137. The routing electrode 133a is electrically connected to the external electrode 136a via the castellation electrode 138a. A castellation electrode 138c is formed at the corner portion at the +X- and the −Z-sides of the front surface of the castellation 137. The routing electrode 133b is electrically connected to the external electrode 136b via the castellation electrode 138c.

Forming the conductive metal film by, for example, sputtering or vacuum evaporation using, for example, a metal mask stencil allows forming the external electrodes 136a and 136b and the castellation electrodes 138a and 138c similarly to the connecting electrode 132a or a similar electrode. The film structure of the metal film is similar to the connecting electrode 132a or a similar electrode. The metal film may be formed by the photolithography and etching.

The lid 120 and the base 130 are bonded by a bonding material 154. The bonding material 154 is arranged between the bonding surface 122 and a front surface 131. The lid 120 and the base 130 may be directly bonded to each other. The piezoelectric vibrating piece 10 is held to the base 130 at the three points with the conductive adhesives 151 and 152 and the adhesive 153. The conductive adhesive 151 is arranged between the extraction electrode 14a and the connecting electrode 132a. The conductive adhesive 152 is arranged between an extraction electrodes 14b and the connecting electrode 132b. The adhesive 153 is arranged between the index mark 17 and the corresponding mark 134. The extraction electrode 15a is electrically connected to the connecting electrode 132a with the conductive adhesive 151. The extraction electrode 14a is electrically connected to the connecting electrode 132b with the conductive adhesive 152. As the conductive adhesives 151 and 152, silicon-based or polyimide-based conductive adhesive is used.

As to the adhesives 153, the conductive adhesive similar to the conductive adhesives 151 and 152 may be used. A non-conductive adhesive may be used. The adhesive 153 is arranged at the central portion of the side portion 18b of the piezoelectric vibrating piece 10. However, this should not be construed in a limiting sense. For example, the adhesive 153 may be arranged at a state shifted in the ±Z direction from the central portion. The piezoelectric vibrating piece 10 is not limited to be supported at the three points. The piezoelectric vibrating piece 10 may be supported at the two points of the conductive adhesives 151 and 152 without arranging the adhesive 153.

As illustrated in FIG. 6B, the piezoelectric vibrating piece 10 is disposed in a cavity 111. The cavity 111 is formed of the depressed portion 121 of the lid 120 and the front surface 131 of the base 130. The cavity 111, for example, is set under a vacuum atmosphere. However, this should not be construed in a limiting sense. The cavity 111 may seal inert gas such as argon gas and nitrogen gas.

Thus, according to the piezoelectric device 100, confirming the relative position between the index mark 17 and the corresponding mark 134 allows confirming that the piezoelectric vibrating piece 10 is held at an appropriate position easily. Thus, the piezoelectric device 100 that has the excellent quality and the improved reliability can be provided. The piezoelectric vibrating piece 10 according to the first embodiment is used in the above-described embodiment. However, the piezoelectric vibrating pieces 20, 30, 40, and 50 described in the second to the fifth embodiments may be used in place of this.

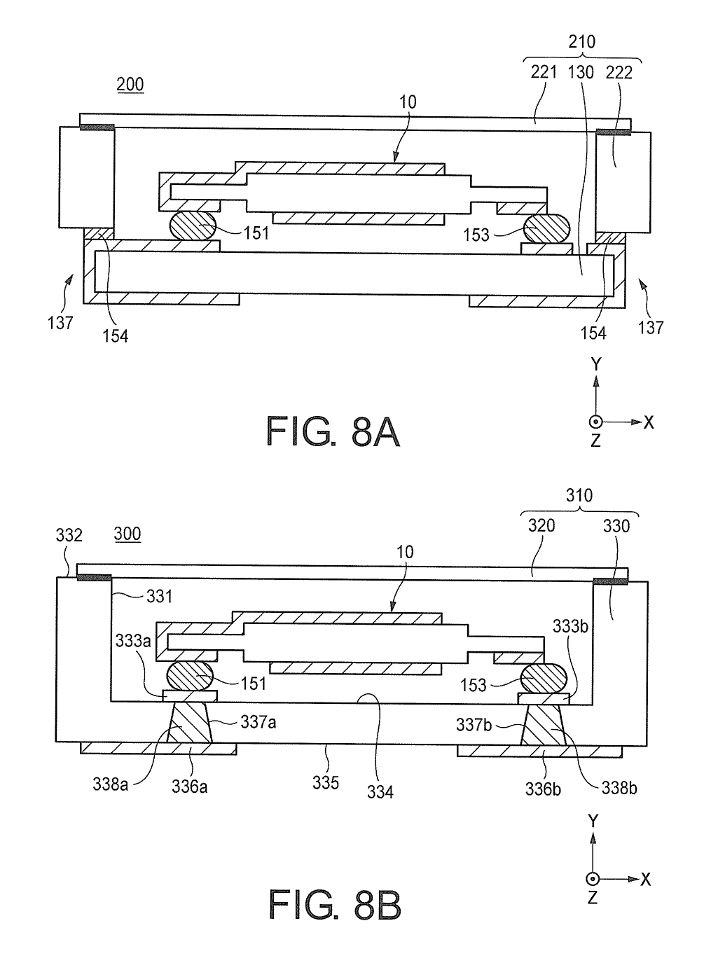

Further, a description will be given of piezoelectric devices 200 and 300 according to a modification with reference to FIGS. 8A and 8B. In the following description, like reference numerals designate identical or corresponding parts of the above-described embodiments, and therefore such elements will not be further elaborated here. FIG. 8A is a cross-sectional view of the piezoelectric device 200 according to the modification. FIG. 8B is a cross-sectional view of the piezoelectric device 300 according to another modification.

As illustrated in FIG. 8A, the piezoelectric device 200 includes a package 210. The package 210 includes the base 130, a lid 221, and a framing portion 222. The lid 221 is made of a metal plate-shaped member such as an iron, a nickel, a 42 alloy, and a Kovar. The framing portion 222 is used for forming a space that houses the piezoelectric vibrating piece 10. While the framing portion 222 is, for example, made of a glass similarly to the base 130, the framing portion 222 may be made of a silicon, a ceramics, a resin, a metal, or a similar material in place of the glass.

The base 130 and the framing portion 222 are bonded via the bonding material 154. The base 130 and the framing portion 222 may be directly bonded to each other. The lid 221 is bonded to the framing portion 222 via a brazing material such as a silver (Ag) by seam welding, for example, from the +Y-side of the framing portion 222. The lid 221 may be bonded to the framing portion 222 via a bonding material.

As illustrated in FIG. 8B, the piezoelectric device 300 includes a package 310. The package 310 includes a lid 320 and a base 330. The lid 320 is, for example, made of a metal plate-shaped member such as an iron, a nickel, a 42 alloy, and a Kovar, similarly to the lid 221 illustrated in FIG. 8A. As illustrated in FIG. 8B, the base 330 includes a depressed portion 331 and a bonding surface 332. The depressed portion 331 is formed at the central portion of the front surface (+Y-side surface). The bonding surface 332 surrounds the depressed portion 331. The depressed portion 331 is used as a space that houses the piezoelectric vibrating piece 10.

The base 330 includes connecting electrode (not illustrated) and routing electrodes 333a and 333b on a bottom surface (+Y-side surface) 334 of the depressed portion 331. The connecting electrode is connected via the piezoelectric vibrating piece 10 and the conductive adhesives 151 and 152. The connecting electrode is electrically connected to the routing electrodes 333a and 333b. The base 330 includes through holes 337a and 337b. The through holes 337a and 337b penetrate the bottom surface 334 and a back surface (−Y-side surface) 335.

The through holes 337a and 337b are each formed into a truncated cone shape in which its bore diameter is brought to spread to be gradually larger from the bottom surface 334 toward the back surface 335. The through holes 337a and 337b internally includes through electrodes 338a and 338b, respectively. The routing electrodes 333a and 333b are electrically connected to external electrodes 336a and 336b by the through electrodes 338a and 338b. The through electrodes 338a and 338b are formed by filling the through holes 337a and 337b of the base 130 by, for example, copper plating.

Configurations of the piezoelectric devices 200 and 300 according to a modification described above can be appropriately combined. For example, as an electrode of the base 130 of the piezoelectric device 200 illustrated in FIG. 8A, the through electrodes 338a and 338b as illustrated in FIG. 8B may be disposed. As a package of the piezoelectric device, various forms can be applied other than the forms illustrated in FIGS. 6A and 6B and FIGS. 8A and 8B.

### Method for Fabricating Piezoelectric Device 100

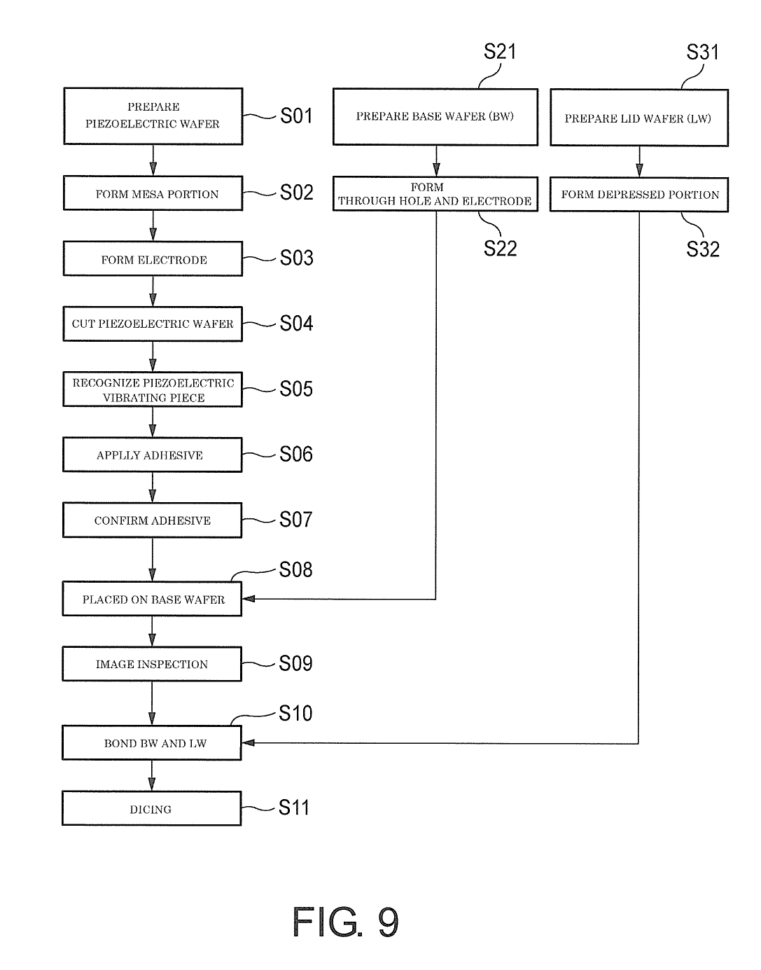

Next, a description will be given of a method for fabricating the piezoelectric device 100 with reference to FIGS. 9 to 11. In the following description, like reference numerals designate identical or corresponding parts of the above-described embodiments, and therefore such elements will not be further elaborated here. A description will be given according to the flowchart illustrated in FIG. 9. First, a piezoelectric wafer on which multiple patterning is performed for obtaining the piezoelectric vibrating pieces 10 is prepared (Step S01). A base wafer BW on which multiple patterning is performed for obtaining the bases 130 is prepared (Step S21). A lid wafer LW on which multiple patterning is performed for obtaining the lids 120 is prepared (Step S31). Afterwards, the respective wafers are processed.

Following Step S01, the thickness of the vibrating portion is adjusted and the mesa portions 13a and 13b are formed on the front surface and the back surface of the piezoelectric wafer (Step S02). For adjustment of the thickness of the vibrating portion and formation of the mesa portion 13a or a similar mesa portion, for example, the photolithography and etching are used. However, the machining such as cutting may be used in place of the photolithography and etching.

Next, the excitation electrodes 14 and 15 and the extraction electrodes 14a and 15a are formed on the front surface and the back surface of the piezoelectric wafer. At the same time, the index mark 17 is formed on the back surface of the piezoelectric wafer (Step S03). For formation of the excitation electrode 14 or a similar electrode, for example, the photolithography and etching are used. However, for formation of the excitation electrode 14 or a similar electrode, sputtering or vacuum evaporation using a metal mask stencil or a similar method may be used. The extraction electrode 14a is formed to the side surface 12c of the piezoelectric vibrating piece 10 (See FIGS. 1A and 1B), for example, by forming the conductive metal film on the inner peripheral surface of the through hole preliminary formed on the piezoelectric wafer. Next, the piezoelectric wafer is cut along the preliminary set scribe line. Accordingly, the individual piezoelectric vibrating pieces 10 are formed (forming process, Step S04).

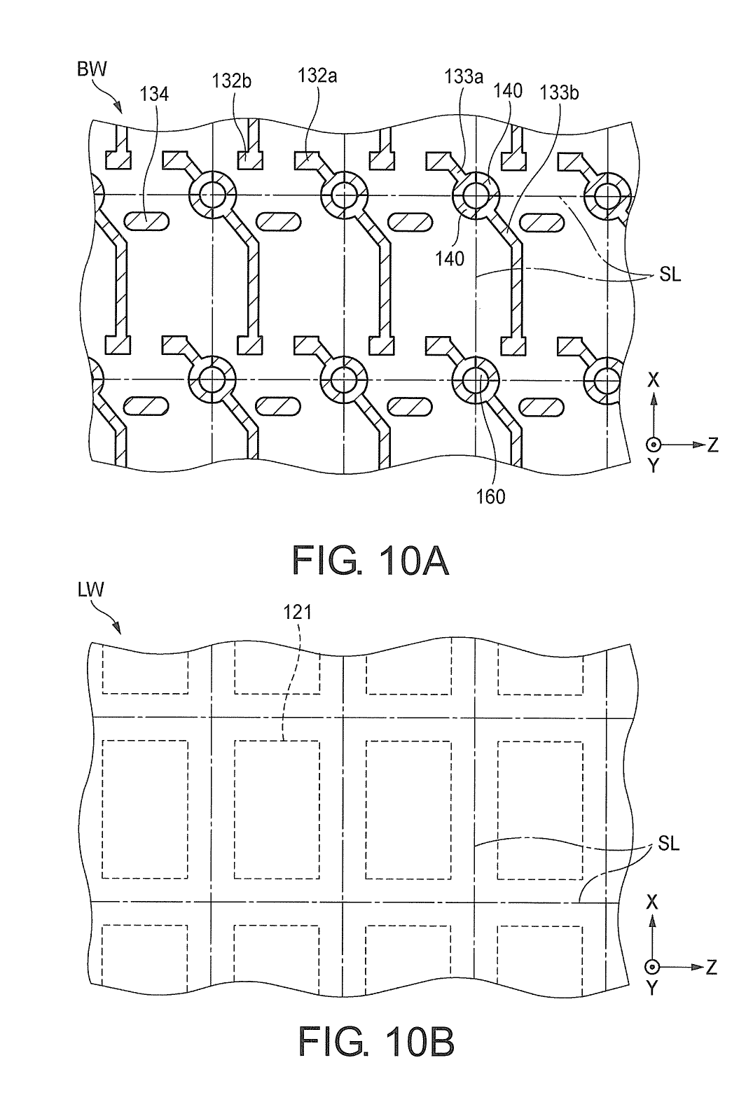

On the other hand, following Step S21, a through hole 160 and various electrodes are formed on the base wafer BW (Step S22). As illustrated in FIG. 10A, the through hole 160 with a circular cross-section is formed on the base wafer BW. The through hole 160 is for forming the castellation 137 in the piezoelectric device 100. The through hole 160 is formed by, for example, the photolithography and etching, but may be formed by the machining such as cutting.

The connecting electrodes 132a and 132b and the routing electrodes 133a and 133b are formed on the front surface (+Y-side surface) of the base wafer BW. At the same time, the corresponding mark 134 is formed on the front surface of the base wafer BW. The through hole 160 forms a castellation electrode 138a or a similar electrode on the side surface. The external electrodes 136a and 136b are formed on the back surface (−Y-side surface) of the base wafer BW.

As illustrated in FIG. 10B, following Step S31, the depressed portion 121 is formed on the back surface (−Y-side surface) of the lid wafer LW (Step S32). The depressed portion 121 is formed by, for example, the photolithography and etching, but may be formed by the machining such as cutting.

Next, as illustrated in FIG. 9, following Step S04, the individual piezoelectric vibrating pieces 10 are taken out, the image of the piezoelectric vibrating piece 10 is taken by the imaging apparatus such as a camera, and the shape of the piezoelectric vibrating piece 10 is recognized (Step S05). Various manipulators such as a robot hand may be used when taking out the piezoelectric vibrating piece 10.

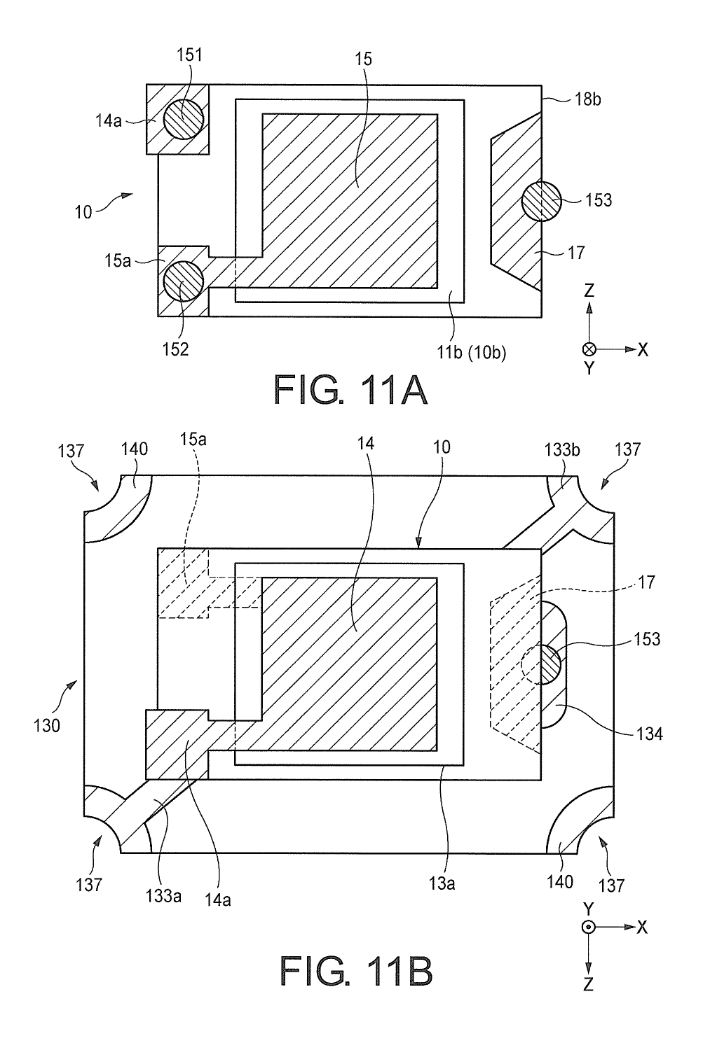

Next, the conductive adhesive is applied to the predetermined part of the piezoelectric vibrating piece 10 (Step S06). As illustrated in FIG. 11A, the conductive adhesives 151 and 152 are applied to the extraction electrodes 14a and 15a of the back surface 10b of the piezoelectric vibrating piece 10, and the adhesive 153 is applied to the index mark 17 using the shape of the piezoelectric vibrating piece 10 recognized in Step S05. The adhesive 153 may be the conductive adhesive as described above. When applying the conductive adhesive 151 or a similar adhesive, the adhesive that is discharged from three nozzles arranged in advance, the adhesive that is sequentially discharged so that one nozzle moves to three areas, or a similar adhesive application is used. In FIG. 11A, the adhesives 153 is applied so as to protrude from the index mark 17. However, this should not be construed in a limiting sense. The adhesives 153 may be applied so as to be included in the index mark 17. The adhesive 153 may not be applied to the index mark 17.

Next, the conductive adhesives 151 and 152 and the adhesive 153 are confirmed (application confirmation process, Step S07). The conductive adhesive 151 or a similar adhesive is confirmed by obtaining the image of the piezoelectric vibrating piece 10 with the imaging apparatus such as a camera. The imaging apparatus used when recognizing the shape of the piezoelectric vibrating piece 10 described above may be used. Based on the image taken by the image apparatus, the position on which the conductive adhesive 151 or a similar adhesive is applied and the amount of application are confirmed. The amount of application is determined based on the size (area in the image) of the conductive adhesive 151 or a similar adhesive.

In Step S07, when the adhesive 153 is compared with the index mark 17, the position where the conductive adhesive is applied and the amount of application are confirmed. At this time, even if the piezoelectric vibrating piece 10 is transparent, the index mark 17 can be confirmed with the image. So when the adhesive 153 is compared with the index mark 17, it is possible to confirm the position where the adhesive 153 is to be applied and the amount of application exactly. When it is determined the position where the adhesive 151 or a similar adhesive is to be applied and the amount of application is not appropriate, the repair of the corresponding part is attempted or the piezoelectric vibrating piece 10 is removed. Then, the process proceeds to the next process of placing the next piezoelectric vibrating piece 10.

Next, as illustrated in FIG. 11B, the piezoelectric vibrating piece 10 on which the conductive adhesive 151 or a similar adhesive is applied is placed on the base wafer BW after Step S22 (Step S07). Thus, the piezoelectric vibrating piece 10 is held to the base wafer BW via the conductive adhesive 151 or a similar adhesive. The piezoelectric vibrating piece 10 may be placed on the base wafer BW by a manipulator whose movement amount is set in advance or a similar machine, or may be placed at the same time that the image of the image apparatus is observed. When the image of the image apparatus is used, the piezoelectric vibrating piece 10 may be placed at the same time that the index mark 17 of the piezoelectric vibrating piece 10 is compared with the corresponding mark 134 of the base wafer BW.

In Step S06 described above, the adhesive 153 is applied so as to protrude from the index mark 17. Therefore, as illustrated in FIG. 11B, if the piezoelectric vibrating piece 10 is placed on the base wafer BW, the adhesive 153 protrudes on the corresponding mark 134. Thus, the presence of the adhesive 153 can be confirmed from the image of the image apparatus.

Next, an inspection whether the piezoelectric vibrating piece 10 is appropriately mounted on the base wafer BW or not is made (confirmation process, Step S09). The inspection is determined based on the image obtained by the image apparatus, for example. This inspection observes the relative positional relationship between the index mark 17 of the piezoelectric vibrating piece 10 and the corresponding mark 134 of the base wafer BW and confirms the position where the piezoelectric vibrating piece 10 is held. When it is determined that the position where the piezoelectric vibrating piece 10 is mounted on the base wafer BW is not appropriate, the process on the part is returned to Step S05, and then the piezoelectric vibrating piece 10 is attempted to be placed on the base wafer BW again; or the piezoelectric device at the part is recorded as faulty to proceed to the subsequent process.

Next, the base wafer BW on which the piezoelectric vibrating piece 10 is mounted is bonded to the lid wafer LW after Step S32 via the bonding material 154 (holding process, Step S10). The base wafer BW is bonded to the lid wafer LW, for example, under a vacuum atmosphere or an inert gas atmosphere such as a nitrogen gas. Afterwards, the bonded wafer is cut along a scribe line SL using a dicing saw or a similar tool to complete the individual piezoelectric devices 100.

Thus, according to the method for fabricating the piezoelectric device 100, when the adhesive 153 is compared with the index mark 17, it is possible to confirm the position where the adhesive 153 is to be applied and the amount of application easily. Additionally, when the piezoelectric vibrating piece 10 is placed on the base wafer BW (the base 130), relative position of the piezoelectric vibrating piece 10 to the base wafer BW can be confirmed easily by comparison of the index mark 17 with the corresponding mark 134. Thus, since the occurrence of defective due to incomplete mounting of the piezoelectric vibrating piece 10 during fabrication is reduced, the piezoelectric device 100 that has the excellent quality and the improved reliability can be provided.

A part of the steps illustrated in FIG. 9 may be skipped. The machining process of the base wafer BW (Step S22) and the machining process of the lid wafer LW (Step S32), which are described above, may be carried out at the same time with the machining process of piezoelectric wafer (Steps S02 to S04 or a similar step). In this case, fabricating time and fabricating cost of the piezoelectric device 100 are reduced. The method for fabricating of the piezoelectric device 100 illustrated in FIGS. 6A and 6B is provided in FIG. 9 to FIG. 11B, but this is substantially similar to the methods for fabricating the piezoelectric devices 200 and 300 illustrated in FIGS. 8A and 8B except for the process of the base wafer BW.

The piezoelectric vibrating piece, the piezoelectric device, and the method for fabricating the piezoelectric device of this disclosure have been described above. However, this disclosure is not limited to the above-described explanation, and various changes may be made without departing from the spirit of the disclosure.

For example, in the respective embodiments described above, the piezoelectric vibrating piece 10 or a similar piezoelectric vibrating piece is not limited to an AT-cut quartz-crystal vibrating piece. The piezoelectric vibrating piece 10 or a similar piezoelectric vibrating piece may employ a BT-cut, a GT-cut, an XT-cut, or a similar cut crystal element. The piezoelectric vibrating piece 10 or a similar piezoelectric vibrating piece may be a tuning-fork type quartz-crystal vibrating piece. The piezoelectric vibrating piece 10 is not limited to a quartz-crystal vibrating piece, but may employ other materials such as a lithium tantalate and a lithium niobate. The piezoelectric device 100 is provided as a piezoelectric resonator, but may be an oscillator. In the case of the oscillator, an IC or a similar circuit is mounted on the base 130, the extraction electrode 14a or a similar electrode of the piezoelectric vibrating piece 10 and the external electrode 136a or a similar electrode of the base 130 are electrically connected to the IC, respectively.

In the above-described piezoelectric vibrating piece, the index mark may be formed of a material same as a material for the excitation electrode and the extraction electrode. The index mark may be formed to have a wider width in the side portion on the opposite side than a width at a center. The index mark may be formed in a trapezoidal shape. The index mark may be formed to include all of the side portion on the opposite side.

The disclosure may be a piezoelectric device that includes the above-described piezoelectric vibrating piece and a base that supports the piezoelectric vibrating piece. The base includes a corresponding mark corresponding to the index mark of the piezoelectric vibrating piece.

The disclosure may be a method for fabricating a piezoelectric device that includes: a forming process for forming the above-described piezoelectric vibrating piece; a supporting process for supporting the piezoelectric vibrating piece on a base; and a confirming process for confirming a position where the piezoelectric vibrating piece is supported, by observing the index mark of the piezoelectric vibrating piece and the corresponding mark disposed at the base. In the method for fabricating the piezoelectric device, the supporting process may include: applying an adhesive to the back surface of the piezoelectric vibrating piece and confirming the position where the adhesive is applied.

With the disclosure, it is possible to confirm the mounting position with respect to the base easily and to confirm the position of the adhesive applied position and the amount of application easily. This allows avoiding the bonding failure between the piezoelectric vibrating piece and the base.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A piezoelectric vibrating piece, comprising:
an excitation electrode, being formed in a vibrating portion; and
an extraction electrode, being extracted from the excitation electrode to one side portion, wherein
the piezoelectric vibrating piece includes a front surface and a back surface, at least one of the front surface and the back surface including an index mark formed in a region, the region including at least a part of a side portion on an opposite side of the one side portion, and the region allowing application of an adhesive.

2. The piezoelectric vibrating piece according to claim 1, wherein
the index mark is formed of a material same as a material for the excitation electrode and the extraction electrode.

3. The piezoelectric vibrating piece according to claim 1, wherein
the index mark is formed to have a wider width in the side portion on the opposite side than a width at a center.

4. The piezoelectric vibrating piece according to claim 3, wherein
the index mark is formed in a trapezoidal shape.

5. The piezoelectric vibrating piece according to claim 1, wherein
the index mark is formed to include all of the side portion on the opposite side.

6. A piezoelectric device, comprising:
the piezoelectric vibrating piece according to claim 1; and
a base that supports the piezoelectric vibrating piece, wherein
the base includes a corresponding mark corresponding to the index mark of the piezoelectric vibrating piece.

7. A method for fabricating a piezoelectric device, comprising:
a forming process for forming the piezoelectric vibrating piece according to claim 1;
a supporting process for supporting the piezoelectric vibrating piece on a base; and
a confirming process for confirming a position where the piezoelectric vibrating piece is supported, by observing the index mark of the piezoelectric vibrating piece and the corresponding mark disposed at the base.

8. The method for fabricating the piezoelectric device according to claim 7, wherein the supporting process includes:
applying an adhesive to the back surface of the piezoelectric vibrating piece and confirming the position where the adhesive is applied.
